(19) United States
(12) Patent Application Publication
(10) Pub. No.: US 2026/0031782 A1
(43) Pub. Date: Jan. 29, 2026

(54) FILTER CIRCUIT, FILTER, AND ELECTRONIC DEVICE

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Shuo YANG, Beijing (CN); Yue LI, Beijing (CN); Chunnan FENG, Beijing (CN); Yuelei XIAO, Beijing (CN); Qichang AN, Beijing (CN); Huiying LI, Beijing (CN); Yulin FENG, Beijing (CN); Xue CAO, Beijing (CN)

(21) Appl. No.: 18/996,909

(22) PCT Filed: Apr. 16, 2024
(86) PCT No.: PCT/CN2024/088111

§ 371 Date: Jan. 17, 2025

(30) Foreign Application Priority Data
May 15, 2023 (CN) 202310545610.9

(51) Int. Cl. H03H 7/01

(52) U.S. Cl. CPC H03H 7/0161; H03H 7/1741

(57) ABSTRACT

A filter circuit, a filter, and an electronic device are disclosed. The filter circuit includes: a first port and a second port arranged opposite to each other, a grounding terminal, a series branch between the first port and the second port, and at least one parallel branch connected with the series branch; where the series branch includes at least one series resonance unit arranged in sequence, each of the at least one parallel branch includes a parallel resonance unit, and the parallel resonance unit is connected with the grounding terminal.

### CROSS-REFERENCE TO RELATED APPLICATIONS

This application is a National Stage of International Application No. PCT/CN2024/088111, filed on Apr. 16, 2024, which claims priority to Chinese Patent Application No. 202310545610.9, filed with the China National Intellectual Property Administration on May 15, 2023, and entitled “Filter Circuit, Filter, and Electronic Device”, the content of which is hereby incorporated by reference in its entirety.

### TECHNICAL FIELD

The present disclosure relates to the field of communication technology, and in particular to a filter circuit, a filter, and an electronic device.

### BACKGROUND

As an essential and important component in communication systems, filters have a very wide range of applications.

### SUMMARY

The present disclosure provides a filter circuit, a filter, and an electronic device, and specific solutions are as follows.

Embodiments of the present disclosure provide a filter circuit, including:
a first port and a second port arranged opposite to each other, a grounding terminal, a series branch between the first port and the second port, and at least one parallel branch connected with the series branch;
where the series branch includes at least one series resonance unit arranged in sequence, each of the at least one parallel branch includes a parallel resonance unit, and the parallel resonance unit is connected with the grounding terminal.

Optionally, in embodiments of the present disclosure, each series resonance unit and each parallel resonance unit both include an input terminal and an output terminal arranged opposite to each other, a first capacitor, a second capacitor and an inductor;
a first electrode of the first capacitor and a first electrode of the second capacitor are both connected with the input terminal, and a second electrode of the first capacitor is connected with a first electrode of the inductor;
a second electrode of the second capacitor and a second electrode of the inductor are both connected with the output terminal.

Optionally, in embodiments of the present disclosure, the filter circuit includes one series resonant unit, an input terminal of the series resonance unit is connected with the first port, an output terminal of the series resonance unit is connected with an input terminal of each parallel resonance unit and is connected with the second port, and an output terminal of each parallel resonance unit is connected with the grounding terminal.

Optionally, in embodiments of the present disclosure, the at least one series resonant unit includes a first series resonant unit and a second series resonant unit sequentially arranged between the first port and the second port, an input terminal of the first series resonance unit is connected with the first port, an output terminal of the first series resonance unit is connected with an input terminal of the second series resonance unit, an input terminal of each parallel resonance unit is respectively connected with the output terminal of the first series resonance unit and the input terminal of the second series resonant unit, and an output terminal of each parallel resonance unit is connected with the grounding terminal.

Optionally, in embodiments of the present disclosure, the series branch further includes a third capacitor, a first electrode of the third capacitor is connected with the output terminal of the first series resonance unit, and a second electrode of the third capacitor is connected with the input terminal of each parallel resonance unit.

Optionally, in embodiments of the present disclosure, the series branch further includes a fourth capacitor, a first electrode of the fourth capacitor is connected with the input terminal of the second series resonant unit, and a second electrode of the fourth capacitor is connected with the input terminal of each parallel resonance unit.

Optionally, in embodiments of the present disclosure, the filter circuit includes a plurality of parallel resonance units, the series branch further includes at least one fifth capacitance, a first electrode and a second electrode of each of the at least one fifth capacitor are respectively connected with input terminals of two adjacent parallel resonance units.

Optionally, in embodiments of the present disclosure, a connecting line between a capacitor and an inductor in the filter circuit is a thick and short connecting line.

Optionally, in embodiments of the present disclosure, a quantity of the at least one series resonance unit is equal to a quantity of transmission zero points generated by the filter circuit at high frequency out-of-band suppression.

Optionally, in embodiments of the present disclosure, a quantity of at least one parallel resonance unit is equal to a quantity of the transmission zero points generated by the filter circuit at low frequency out-of-band suppression.

Correspondingly, embodiments of the present disclosure provide a filter, including: the above filter circuit.

Optionally, in embodiments of the present disclosure, each series resonance unit and each parallel resonance unit in the filter both include an input terminal and an output terminal arranged opposite to each other, a first capacitor, a second capacitor and an inductor; a first electrode of the first capacitor and a first electrode of the second capacitor are both connected with the input terminal, and a second electrode of the first capacitor is connected with a first electrode of the inductor; a second electrode of the second capacitor and a second electrode of the inductor are both connected with the output terminal; the inductor includes a base substrate, a metallized through hole penetrating through the base substrate, and re-distribution layer wirings respectively arranged on opposite sides of the base substrate.

Optionally, in embodiments of the present disclosure, a substrate of the filter is a glass substrate.

Optionally, in embodiments of the present disclosure, the filter is a band-pass filter.

Correspondingly, embodiments of the present disclosure provide an electronic device, including: the above filter.

### BRIEF DESCRIPTION OF FIGURES

FIG. 1 is a schematic structural diagram of a filter according to an embodiment of the present disclosure;

FIG. 2 is a schematic structural diagram of a series resonant unit and a parallel resonant unit in a filter according to an embodiment of the present disclosure;

FIG. 3 is a schematic structural diagram of a series resonant unit and a parallel resonant unit in a filter according to an embodiment of the present disclosure;

FIG. 4 is a schematic structural diagram of a filter according to an embodiment of the present disclosure;

FIG. 5 is an S-curve diagram of the filter shown in FIG. 4;

FIG. 6 is a schematic structural diagram of a filter according to an embodiment of the present disclosure;

FIG. 7 is an S-curve diagram of the filter shown in FIG. 6;

FIG. 8 is a schematic structural diagram of a filter according to an embodiment of the present disclosure;

FIG. 9 is an S-curve diagram of the filter shown in FIG. 8;

FIG. 10 is a schematic structural diagram of a filter according to an embodiment of the present disclosure;

FIG. 11 is an S-curve diagram of the filter shown in FIG. 10;

FIG. 12 is a schematic structural diagram of a filter according to an embodiment of the present disclosure;

FIG. 13 is an S-curve diagram of the filter shown in FIG. 12;

FIG. 14 is a schematic structural diagram of a filter according to an embodiment of the present disclosure;

FIG. 15 is an S-curve diagram of the filter shown in FIG. 14;

FIG. 16 is a schematic structural diagram of a filter according to an embodiment of the present disclosure;

FIG. 17 is an S-curve diagram of the filter shown in FIG. 16;

FIG. 18 is a schematic structural diagram of an inductor in a filter according to an embodiment of the present disclosure.

### DETAILED DESCRIPTION

For making objectives, technical solutions and advantages of embodiments of the present disclosure clearer, technical solutions of embodiments of the present disclosure will be clearly and completely described below in conjunction with accompanying drawings in embodiments of the present disclosure. Apparently, embodiments described are some rather than all of embodiments of the present disclosure. Embodiments in the present disclosure and features of embodiments may be combined with each other without conflict. Based on embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. The words “first”, “second”, etc. used in the present disclosure do not indicate any order, quantity or importance, but are only used to distinguish different components. The word “including” or “comprising”, etc. indicates that elements or objects before the word include elements or objects after the word and their equivalents, without excluding other elements or objects. The word “connection” or “link”, etc. is not limited to physical or mechanical connections, but may include electrical connections, whether direct or indirect. “Upper”, “lower”, etc. are only used to indicate a relative positional relationship, and when an absolute position of a described object changes, the relative positional relationship may also change accordingly.

It should be noted that a size and a shape of each figure in the drawings do not reflect a true scale, but only for illustrating the present disclosure. Throughout the drawings, identical or similar reference numerals denote identical or similar elements or elements having identical or similar functions.

At present, with the development of Internet of Things, Internet of Vehicles, Intelligent Terminals and other customs, the explosion of the information age has spread to every corner. As a key device in signal transmission, the filter can play a role in allowing specific signals to pass through and suppressing useless signals. Filter performances such as smaller size, lower insertion loss, better out-of-band suppression and higher operating frequency band become particularly important.

In view of this, an embodiment of the present disclosure provides a filter circuit, a filter, and an electronic device. By setting a quantity of series resonance units and a quantity of parallel resonance units, quantity control for zero points outside a high frequency band and zero points outside a low frequency band is realized, to realize adjustment of out-of-band suppression requirements of the filter. A three-dimensional inductor with small size, high Q value and low loss can also be applied to the filter, to realize low insertion loss in a passband of the filter. In addition, a circuit design in the present disclosure can also be applied to the field of integrated passive technology, to realize the object of miniaturization and low cost of the filter.

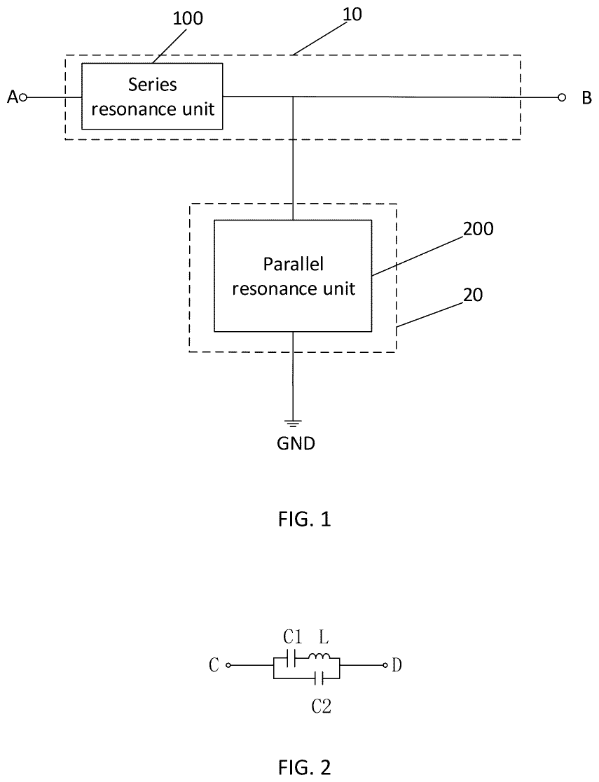

As shown in FIG. 1, an embodiment of the present disclosure provides a filter circuit, including: a first port A and a second port B arranged opposite to each other, a grounding terminal GND, a series branch 10 between the first port A and the second port B, at least one parallel branch 20 connected with the series branch 10.

The series branch 10 includes at least one series resonant unit 100 arranged in sequence. Each of the at least one parallel branch 20 includes a parallel resonant unit 200, and the parallel resonant unit 200 is connected with the grounding terminal GND.

In an embodiment, the first port A is a signal input terminal C, and the second port B is a signal output terminal. In another embodiment, the first port A is a signal input terminal, and the second port B is a signal output terminal. The quantity of the at least one series resonant unit 100 in the series branch 10 may be one or more. Of course, quantities of the first port A, the second port B, and the at least one series resonant unit 100 can be set according to actual application requirements, which are not limited herein.

In an embodiment of the present disclosure, through cooperation of the first port A, the second port B, the grounding terminal GND, the series resonant unit 100 and the parallel resonant unit 200, transmission zero points are increased, out-of-band suppression effect is improved, and it is possible to prepare a band-pass filter with high out-of-band suppression and a plurality of transmission zero points.

In an embodiment of the present disclosure, as shown in FIG. 2, each series resonant unit 100 and each parallel resonant unit 200 includes an input terminal C and an output terminal D arranged opposite to each other, a first capacitor C1, a second capacitor C2 and an inductor L.

A first electrode of the first capacitor C1 and a first electrode of the second capacitor C2 are both connected with the input terminal C, and a second electrode of the first capacitor C1 is connected with a first electrode of the inductor L.

A second electrode of the second capacitor C2 and a second electrode of the inductor L are both connected with the output terminal D.

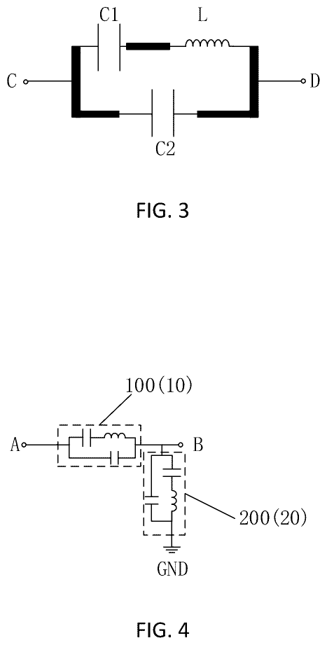

In an embodiment of the present disclosure, a connecting line between a capacitor and an inductor L of the filter circuit is a thick and short connecting line. For example, connecting lines between the first capacitor C1, the inductor L, and the second capacitor C2 are as shown in FIG. 3. A resistance of the thick and short connecting line is related to a width and thickness of the connecting line respectively. Thin lines in FIG. 3 represent connecting lines inside each structure, and thick lines represent connecting lines between different structures. In an actual preparation process, the thickness is determined by process parameters, and on the premise of a certain thickness, a thicker (wider) connecting line is adopted, to reduce losses.

In an embodiment of the present disclosure, a quantity of the at least one series resonant unit 100 is equal to a quantity of transmission zero points generated by the filter circuit at high frequency out-of-band suppression. In an embodiment, when the quantity of the at least one series resonant unit 100 is one, the quantity of transmission zero points generated by the filter circuit at the high frequency out-of-band suppression is one. In an embodiment, when the quantity of the at least one series resonant unit 100 is three, the quantity of transmission zero points generated by the filter circuit at the high frequency out-of-band suppression is three. Accordingly, at least one series resonant unit 100 is arranged according to requirements on the quantity of the transmission zero points of the filter circuit at the high frequency out-of-band suppression, which is not limited herein.

In an embodiment of the present disclosure, a quantity of at least one parallel resonance unit 200 is equal to a quantity of transmission zero points generated by the filter circuit at low frequency out-of-band suppression. In an embodiment, when the quantity of the at least one parallel resonant unit 200 is one, the quantity of transmission zero points generated by the filter circuit at the low frequency out-of-band suppression is one. In an embodiment, when the quantity of the at least one parallel resonant unit 200 is two, the quantity of transmission zero points generated by the filter circuit at the low frequency out-of-band suppression is two. Accordingly, at least one parallel resonance unit 200 is arranged according to requirements on the quantity of the transmission zero points of the filter circuit at the low frequency out-of-band suppression, which is not limited herein.

In a specific implementation process, each series resonant unit 100 mainly plays a role of suppressing the high frequency out-of-band. For a series resonant unit 100, a transmission zero point can be formed at the high frequency out-of-band by using fewer components, and a position of a corresponding transmission zero point can also be adjusted in frequency by finely tuning an inductor L and a capacitor, to ensure a good high frequency out-of-band suppression effect of the filter circuit. Each parallel resonance unit 200 mainly plays a role of low frequency out-of-band suppression. For a parallel resonance unit 200, a transmission zero point can be formed at the low frequency out-of-band by using fewer components, and a position of a corresponding transmission zero point can also be adjusted in frequency by finely tuning an inductor L and a capacitor, to ensure a good low frequency out-of-band suppression effect of the filter circuit.

In an embodiment of the present disclosure, the filter circuit may be arranged according to following circuit structures, but is not limited to the following.

For example, the quantity of the at least one series resonant unit 100 is one, an input terminal of the series resonant unit 100 is connected with the first port A. An output terminal of the series resonance unit 100 is connected with an input terminal of each parallel resonance unit 200 and is connected with the second port B. An output terminal of each parallel resonance unit 200 is connected with the grounding terminal GND.

For example, the at least one series resonance unit 100 includes a first series resonance 101 and a second series resonant unit 102 sequentially arranged between the first port A and the second port B. An input terminal of the first series resonant unit 101 is connected with the first port A. An output terminal of the first series resonance unit 101 is connected with an input terminal of the second series resonance unit 102. An input terminal of each parallel resonance unit 200 is respectively connected with the output terminal of the first series resonance unit 101 and the input terminal of the second series resonant unit 102. An output terminal of each parallel resonance unit 200 is connected with the grounding terminal GND.

For example, the series branch 10 further includes a third capacitor C3. A first electrode of the third capacitor C3 is connected with the output terminal of the first series resonant unit 101. A second electrode of the third capacitor C3 is connected with the input terminal of each parallel resonance unit 200.

For example, the series branch 10 further includes a fourth capacitor C4. A first electrode of the fourth capacitor C4 is connected with the input terminal of the second series resonant unit 102. A second electrode of the fourth capacitor C4 is connected with the input terminal of each parallel resonance unit 200.

For example, the quantity of the parallel resonant units 200 is multiple. The series branch 10 further includes at least one fifth capacitor C5. A first electrode and a second electrode of each of the at least one fifth capacitor C5 are respectively connected with input terminals of two adjacent parallel resonant units 200. In this case, each of the at least one fifth capacitor C5 can isolate two adjacent parallel resonant units 200. The quantity of the at least one fifth capacitor C5 may be one or more. The at least one fifth capacitor C5 may be set according to actual application requirements, which is not limited herein.

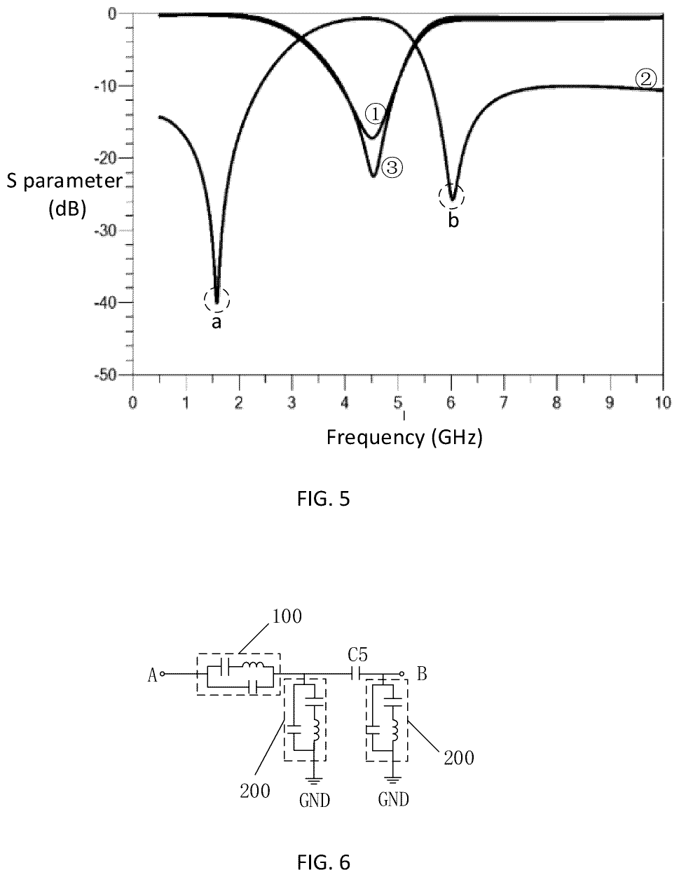

In an embodiment shown in FIG. 4, the filter circuit includes one series resonant unit 100 and one parallel resonant unit 200. In this embodiment, an input terminal of the series resonant unit 100 is connected with a first port A. An output terminal of the series resonant unit 100 is connected with an input terminal of the parallel resonant unit 200 and is connected with a second port B. An output terminal of the parallel resonance unit 200 is connected with a grounding terminal GND. FIG. 5 is an S-curve diagram of the filter circuit shown in FIG. 4. In FIG. 5, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. A dashed box a in FIG. 5 represents a transmission zero point at low frequency suppression, and a dashed box b represents a transmission zero point at high frequency suppression.

It should be noted that, taking the embodiment shown in FIG. 4 as an example, both the input terminal and the output terminal of the series resonant unit 100 are not grounded. Accordingly, the inductor L in the series resonant unit 100 is not grounded. An equivalent low-pass filter circuit may be formed by the inductor L and a capacitor connected with the grounding terminal GND in the parallel resonance unit 200, or formed by the inductor L and a capacitor connected with the grounding terminal GND and parasitized when preparing the inductor L and the capacitor in the parallel resonance unit 200 in a process, to generate a transmission zero point at the high frequency out-of-band suppression, and realize filtering of a high frequency signal. Also, the input terminal of the parallel resonance unit 200 is not connected with the grounding terminal GND, and the output terminal of the parallel resonance unit 200 is connected with the grounding terminal GND. Accordingly, one of electrodes of the inductor L in the parallel resonance unit 200 is connected with the grounding terminal GND. An equivalent high-pass filter circuit may be formed by the inductor L and a capacitor in the series resonant unit 100, or formed by the inductor L and a capacitor parasitized when preparing the capacitor and the inductor L in the series resonant unit 100 in a process, to generate a zero point at the low frequency out-of-band suppression and realize filtering of a low frequency signal. In this case, zero points at the high frequency out-of-band suppression can be increased by increasing the quantity of series resonant units 100. Transmission zero points at the low frequency out-of-band suppression are increased by increasing the quantity of parallel resonance units 200. In this way, it is ensured that the filter circuit provided by embodiments of the present disclosure has a function of a band-pass filter circuit. In a process of actually preparing the filter in an embodiment of the present disclosure, corresponding quantities of series resonant units 100 and parallel resonant units 200 are selected according to characteristics required by actual filter requirements to achieve a desired filtering characteristic.

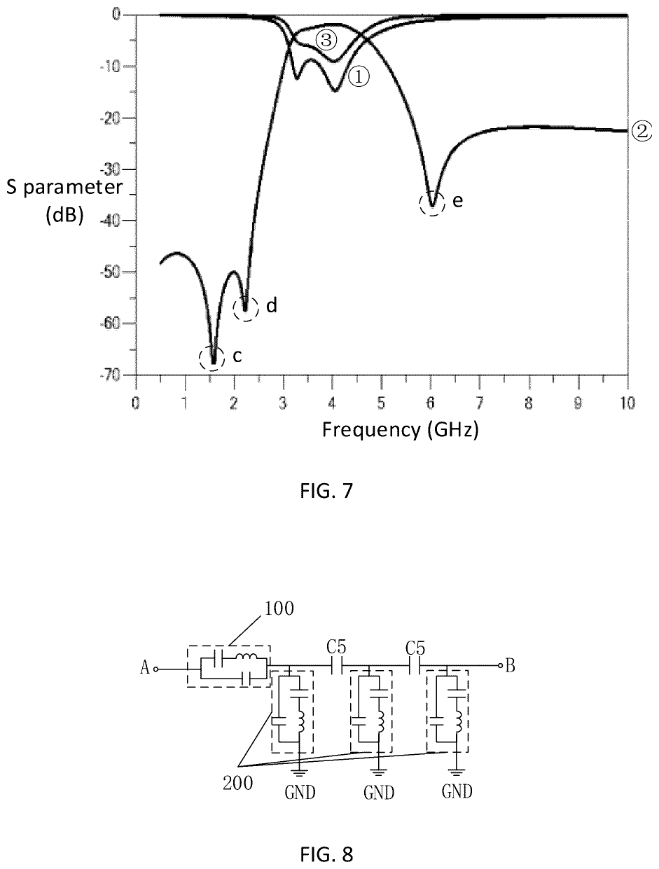

In an embodiment shown in FIG. 6, the filter circuit includes one series resonant unit 100, two parallel resonant units 200 and a fifth capacitor C5. A first electrode and a second electrode of the fourth capacitor C5 are respectively connected with input terminals of the two parallel resonance units 200. An output terminal of each of the parallel resonance units 200 is connected with the grounding terminal GND. FIG. 7 is an S-curve diagram of the filter circuit shown in FIG. 6.

In FIG. 7, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. Dashed boxes c and d in FIG. 7 represent transmission zero points at low frequency suppression, and a dashed box e represents a transmission zero point at high frequency suppression.

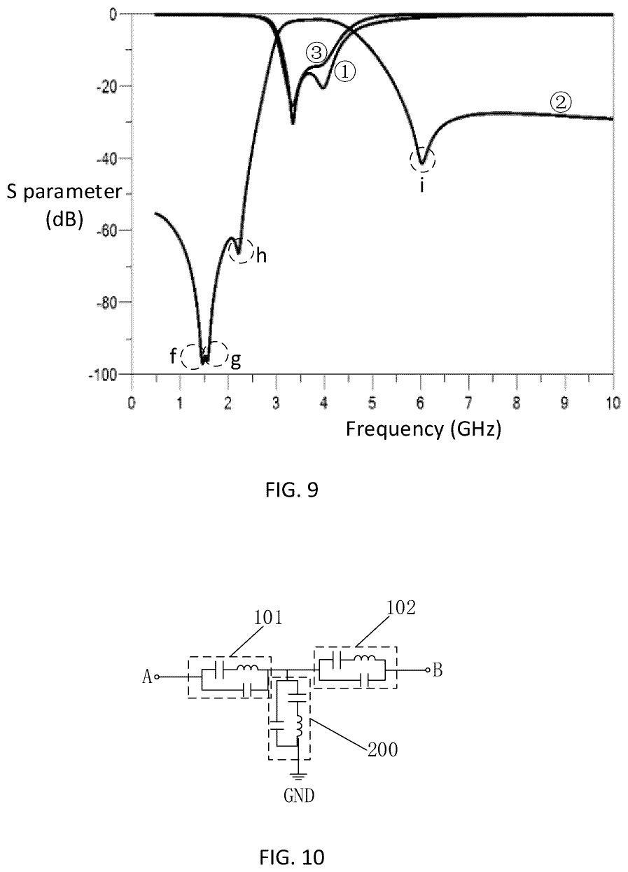

In an embodiment shown in FIG. 8, the filter circuit includes one series resonant unit 100, three parallel resonant units 200, and two fifth capacitors C5. A first electrode and a second electrode of each of the fifth capacitors C5 are respectively connected with input terminals of two adjacent parallel resonance units 200. An output terminal of each of the parallel resonance units 200 is connected with a grounding terminal GND. FIG. 9 is an S-curve diagram of the filter circuit shown in FIG. 8. In FIG. 9, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. Dashed boxes f, g and h in FIG. 9 represent transmission zero points at low frequency suppression, and a dashed box i represents a transmission zero point at high frequency suppression.

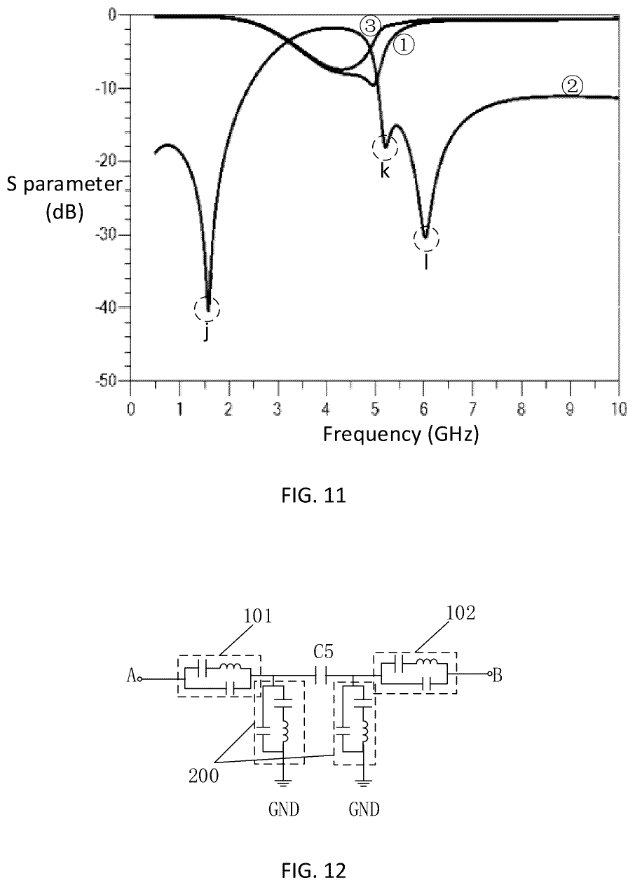

In an embodiment shown in FIG. 10, the filter circuit includes a first series resonance unit 101 and a second series resonance unit 102 sequentially arranged between a first port A and a second port B, and one parallel resonance unit 200. An input terminal of the first series resonance unit 101 is connected with the first port A, an output terminal of the first series resonance unit 101 is connected with an input terminal of the second series resonance unit 101, an output terminal of the second series resonant unit 102 is connected with the second port. An output terminal of the first series resonance unit 101 and an input terminal of the second series resonance unit 102 are connected with the input terminal of the parallel resonance unit 200, and an output terminal of the parallel resonance unit 200 is connected with the grounding terminal GND. FIG. 11 is an S-curve diagram of the filter circuit shown in FIG. 10. In FIG. 11, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. A dashed box j in FIG. 11 represents a transmission zero point at low frequency suppression, and a dashed box k and a dashed box I represent transmission zero points at high frequency suppression.

In an embodiment shown in FIG. 12, the filter circuit includes a first series resonance unit 101 and a second series resonance unit 102 sequentially arranged between a first port A and a second port B, one fifth capacitor C5 and two parallel resonance units 200. A first electrode and a second electrode of the fifth capacitor C5 are respectively connected with input terminals of the two parallel resonance units 200. An input terminal of the first series resonance unit 101 is connected with the first port A, an output terminal of the first series resonance unit 101 is connected with the first electrode of the fifth capacitor C5, an input terminal of the second series resonant unit 102 is connected with the second electrode of the fifth capacitor C5, an output terminal of the second series resonant unit 102 is connected with the second port B, and an output terminal of each of the parallel resonant units 200 is connected with a grounding terminal GND.

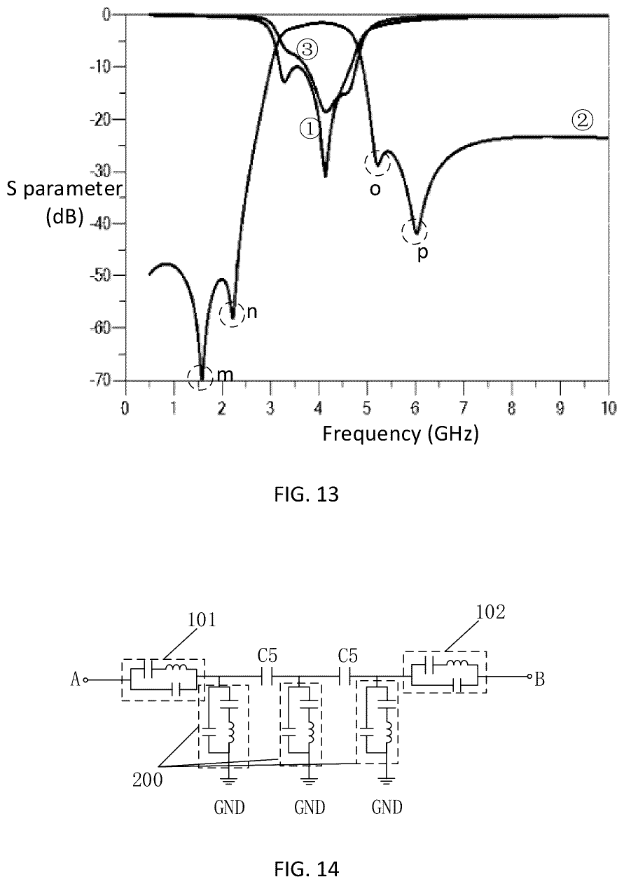

FIG. 13 is an S-curve diagram of the filter circuit shown in FIG. 12. In FIG. 13, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. Dashed boxes m and n in FIG. 13 represent transmission zero points at low frequency suppression, and a dashed box o and a dotted box p represent transmission zero points at high frequency suppression.

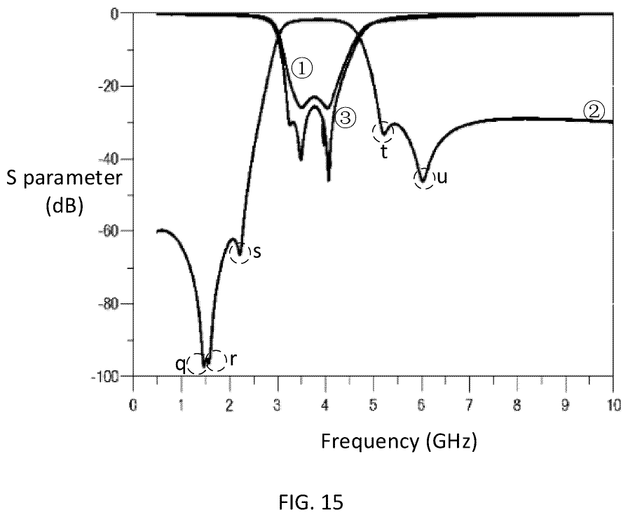

In an embodiment shown in FIG. 14, the filter circuit includes a first series resonance unit 101 and a second series resonance unit 102 sequentially arranged between a first port A and a second port B, two fifth capacitors C5 and three parallel resonance units 200. A first electrode and a second electrode of each fifth capacitor C5 are respectively connected with input terminals of two adjacent parallel resonance units 200. An output terminal of each parallel resonance unit 200 is connected with a grounding terminal GND. FIG. 15 is an S-curve diagram of the filter circuit shown in FIG. 14. In FIG. 15, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. A dashed box q, a dashed box r and a dashed box s in FIG. 15 represent transmission zero points at low frequency suppression, and a dashed box t and a dashed box u represent transmission zero points at high frequency suppression. In an embodiment shown in FIG. 14, the overall out-of-band suppression of the filter circuit is less than 30 dB.

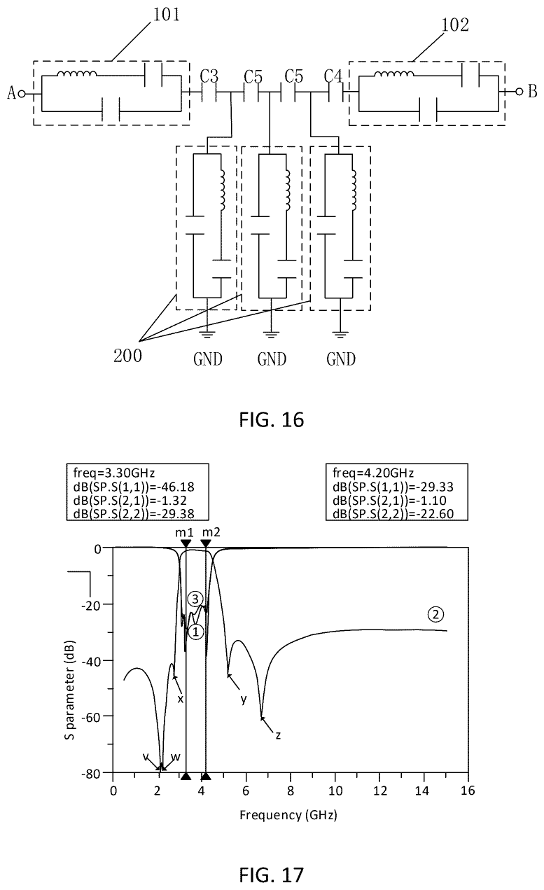

In an embodiment shown in FIG. 16, the filter circuit includes a first series resonance unit 101 and a second series resonance unit 102 sequentially arranged between a first port A and a second port B, two fifth capacitors C5, a third capacitor C3, and a fourth capacitor C4. In an embodiment shown in FIG. 16, the filter circuit may be an N77 band-pass filter operating in a frequency band of 3.30 GHz to 4.20 GHz. FIG. 17 is an S-curve diagram of the filter circuit shown in FIG. 16. In FIG. 17, the abscissa represents a frequency and the ordinate represents an S parameter, where \textcircled{1} shows a schematic diagram of a curve of an input reflection coefficient S11, \textcircled{2} shows a schematic diagram of a curve of a forward transmission coefficient S21, \textcircled{3} shows a schematic diagram of a curve of an output reflection coefficient S22. Symbols v, w and x in FIG. 17 represent transmission zero points at low frequency suppression, and symbols y and z represent transmission zero points at high frequency suppression.

Of course, in an embodiment of the present disclosure, in addition to the filter circuit that may be provided in accordance with the above embodiments, the filter circuit may also be provided in other manners, which is not limited herein.

It should be noted that in practical application, the position and the quantity of the capacitors can be set according to actual requirements. Through the set capacitors, on the one hand, impedance matching between the first port A and the second port B of the filter circuit can be improved, so that the S11 in the S parameter is better, to ensure the signal transmission quality of the filter circuit; on the other hand, the series resonance unit 100 and the parallel resonance unit 200 can form the most basic high-pass filter circuit and low-pass filter circuit in the LC filter, to ensure that that filter circuit can generate a transmission zero point at out-of-band suppression to realize the filter characteristic.

Capacitance values of the capacitors in the filter circuit according to embodiments of the present disclosure can be set to be different. A corresponding capacitance value can be set according to a function of the capacitor. Of course, it is also possible to set the capacitance values of the capacitors to be partially the same, to reduce the design difficulty. Inductance L values of inductors L in the filter circuit according to embodiments of the present disclosure can be set to be different. A corresponding inductance L value can be set according to a function of the inductor. Of course, it is also possible to set the inductance L values of the inductors L to be partially the same, to reduce the design difficulty. In practical applications, the size of the filter circuit and the quantity of the series resonant unit 100 and the parallel resonant unit 200 can be changed, to ensure the filter circuit to cover different frequency bands, and realize out-of-band suppression with different effects.

Based on the same disclosed concept, an embodiment of the present disclosure further provides a filter including the above-mentioned filter circuit. For example, the filter may be an Integrated Passive Device (IPD). The principle of the filter to solve the problem is similar to that of the filter circuit described above. The implementation of the filter can be referred to the implementation of the filter circuit, and the repetition is not repeated. For the specific circuit structure of the filter circuit, reference may be made to the description of the relevant parts above, which will not be repeated here.

In an embodiment of the present disclosure, each series resonant unit 100 and each parallel resonant unit 200 in the filter includes an input terminal A and an output terminal B arranged opposite to each other, a first capacitor C1, a second capacitor C2 and an inductor L. A first electrode of the first capacitor C1 and a first electrode of the second capacitor C2 are both connected with the input terminal A, and a second electrode of the first capacitor C1 is connected with a first electrode of the inductor L. A second electrode of the second capacitor C2 and a second electrode of the inductor L are both connected with the output terminal B. The inductor L includes a base substrate 30, a metallized through hole 40 extending through the base substrate 30, and re-distribution layer wirings 50 respectively arranged on opposite sides of the base substrate 30.

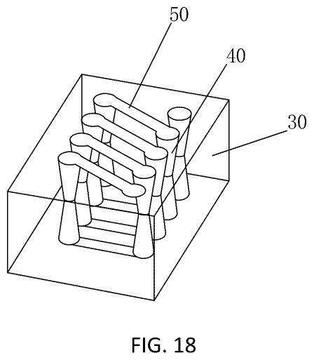

For example, the inductor L is formed by a Re-distribution Layer (RDL) wiring. As shown in FIG. 18, for example, in an actual preparation, a Through Glass Via (TGV) technology can be used to perform laser drilling on a glass substrate, then electroplating is performed to realize a metallized through hole 40, then RDL wirings are respectively set on opposite side surfaces of the glass substrate, and the set RDL wirings are connected through the metallized through hole 40. Therefore, a three-dimensional inductor L design with small size, high Q value and low loss is achieved, to ensure use performance of the filter.

For example, for a single resonant unit, a capacitor and an inductor L may be connected by an RDL wiring. The capacitor further includes a plurality of bonding points. Signals in components can be input and output through the plurality of bonding points, and can also be connected with a grounding terminal GND. For example, the capacitor in the single resonant unit includes an upper electrode layer, a lower electrode layer and a medium between the upper electrode layer and the lower electrode layer. The capacitor may be a plate capacitor.

In an embodiment, the inductor L may also be a two-dimensional wire-wound inductor formed by a resin material, for example, a two-dimensional planar spiral inductor, to ensure diversified design of the filter.

It should be noted that the base substrate 30 of the inductor L may be a glass substrate, a silicon-based substrate, or a ceramic substrate, which is not limited herein. In addition, sizes of the first capacitor C1, the second capacitor C2 and the inductor L can be set according to design requirements of the actual device size, which is not limited herein.

In an embodiment of the present disclosure, the filter is a band-pass filter.

Of course, the filter according to embodiments of the present disclosure includes not only related structures mentioned above. Other structures may also be set according to actual application requirements, and the specific setting may be implemented by referring to the related art, which is not described in detail here.

Base on the same disclosed concept, embodiments of the present disclosure further provide an electronic device including the filter mentioned above. The principle of the electronic device solving the problem is similar to that of the filter described above. Therefore, the implementation of the electronic device can be referred to the implementation of the filter described above, and the repetition is not repeated.

For example, the electronic device may be a radio frequency device.

Although embodiments of the present disclosure have been described, those of skill in the art may otherwise make various modifications and variations to these embodiments once they are aware of the basic inventive concept. Therefore, the claims intend to include embodiments as well as all these modifications and variations falling within the scope of the present disclosure.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. A filter circuit, comprising:
a first port and a second port arranged opposite to each other, a grounding terminal, a series branch between the first port and the second port, and at least one parallel branch connected with the series branch;
wherein the series branch comprises at least one series resonance unit arranged in sequence, each of the at least one parallel branch comprises a parallel resonance unit, and the parallel resonance unit is connected with the grounding terminal.

2. The filter circuit according to claim 1, wherein each series resonance unit and each parallel resonance unit both comprise an input terminal and an output terminal arranged opposite to each other, a first capacitor, a second capacitor and an inductor;
a first electrode of the first capacitor and a first electrode of the second capacitor are both connected with the input terminal, and a second electrode of the first capacitor is connected with a first electrode of the inductor;
a second electrode of the second capacitor and a second electrode of the inductor are both connected with the output terminal.

3. The filter circuit according to claim 2, wherein the filter circuit comprises one series resonant unit, an input terminal of the series resonance unit is connected with the first port, an output terminal of the series resonance unit is connected with an input terminal of each parallel resonance unit and is connected with the second port, and an output terminal of each parallel resonance unit is connected with the grounding terminal.

4. The filter circuit according to claim 2, wherein the at least one series resonant unit comprises a first series resonant unit and a second series resonant unit sequentially arranged between the first port and the second port, an input terminal of the first series resonance unit is connected with the first port, an output terminal of the first series resonance unit is connected with an input terminal of the second series resonance unit, an input terminal of each parallel resonance unit is respectively connected with the output terminal of the first series resonance unit and the input terminal of the second series resonant unit, and an output terminal of each parallel resonance unit is connected with the grounding terminal.

5. The filter circuit according to claim 4, wherein the series branch further comprises a third capacitor, a first electrode of the third capacitor is connected with the output terminal of the first series resonance unit, and a second electrode of the third capacitor is connected with the input terminal of each parallel resonance unit.

6. The filter circuit according to claim 5, wherein the series branch further comprises a fourth capacitor, a first electrode of the fourth capacitor is connected with the input terminal of the second series resonant unit, and a second electrode of the fourth capacitor is connected with the input terminal of each parallel resonance unit.

7. The filter circuit according to claim 2, wherein the filter circuit comprises a plurality of parallel resonance units, the series branch further comprises at least one fifth capacitance, a first electrode and a second electrode of each of the at least one fifth capacitor are respectively connected with input terminals of two adjacent parallel resonance units.

8. The filter circuit according to claim 1, wherein a connecting line between a capacitor and an inductor in the filter circuit is a thick and short connecting line.

9. The filter circuit according to claim 8, wherein a quantity of the at least one series resonance unit is equal to a quantity of transmission zero points generated by the filter circuit at high frequency out-of-band suppression.

10. The filter circuit according to claim 9, wherein a quantity of at least one parallel resonance unit is equal to a quantity of the transmission zero points generated by the filter circuit at low frequency out-of-band suppression.

11. A filter, comprising: the filter circuit according to claim 1.

12. The filter according to claim 11, wherein each series resonance unit and each parallel resonance unit in the filter both comprise an input terminal and an output terminal arranged opposite to each other, a first capacitor, a second capacitor and an inductor; a first electrode of the first capacitor and a first electrode of the second capacitor are both connected with the input terminal, and a second electrode of the first capacitor is connected with a first electrode of the inductor; a second electrode of the second capacitor and a second electrode of the inductor are both connected with the output terminal; the inductor comprises a base substrate, a metallized through hole penetrating through the base substrate, and re-distribution layer wirings respectively arranged on opposite sides of the base substrate.

13. The filter according to claim 12, wherein a substrate of the filter is a glass substrate.

14. The filter according to claim 11, wherein the filter is a band-pass filter.

15. An electronic device, comprising: the filter according to claim 11.
